(19) United States
(12) Patent Application Publication
(10) Pub. No.: US 2008/0164807 A1
(43) Pub. Date: Jul. 10, 2008

(54) Component Based on Organic Light-Emitting Diodes and Method For Producing the Same

(75) Inventors: Michael Hofmann, Dresden (DE); Jan Birnstock, Dresden (DE); Martin Vehse, Dresden (DE)

Correspondence Address: SUTHERLAND ASBILL & BRENNAN LLP, 999 PEACHTREE STREET, N.E., ATLANTA, GA, 30309, US

(73) Assignee: NOVALED GMBH, Dresden (DE)

(21) Appl. No.: 11/574,058

(22) PCT Filed: Aug. 24, 2005
(86) PCT No.: PCT/DE05/01493

§ 371 Date: Oct. 12, 2007

(30) Foreign Application Priority Data
Aug. 25, 2004 (DE) 10 2004 041 371.1

(51) Int. Cl. H01L 27/32; H01J 9/02

(52) U.S. Cl. 313/504; 445/24

(57) ABSTRACT

In order to improve the fill factor as well as the efficiency for a structural element on the basis of an organic light-emitting diode facility, a display is proposed comprising a substrate, a first electrode (130) nearest to the substrate, a second electrode (160) away from the substrate and at least one light-emitting organic layer (150) arranged between both electrodes. The light emitted in the active zone transmits through one of the two electrodes whereby the first electrode is pixel-structured and an isolation layer (150) is arranged between neighbouring pixels. The display according to the invention is characterized in that the isolation layer (150) is optically coupled with the light-emitting layer (150), and has optically effective light-scattering and fill factor increasing heterogeneities (180, 190), whereby the isolation layer is micro-structured to match the pixel structure of the first electrode and is processed onto this.

In addition, the invention concerns also a method for the manufacture of such a display.

The invention concerns a display on the basis of an organic light-emitting diode facility as well as a method for its manufacture.

### BACKGROUND OF THE INVENTION

In recent years there has been an upsurge in the demand for increasingly smaller, space-saving, light and inexpensive display modules and displays for quick and adequate visualisation of data and information. The principle of the cathode steel tube or the liquid crystal display (LCD) is adopted for most of the display elements used at present. In addition to these, there are also flat type display technologies such as plasma displays, vacuum fluorescence or field emission displays which are technically very sophisticated and cost-intensive. With displays on the basis of organic light-emitting diodes (OLEDs), competition for the established technologies has emerged in recent years and this competition is to be taken seriously. The essential advantages of a display facility on the basis of OLEDs are stated as being the provision of brilliant colours, a very high contrast, fast switching times at low temperatures, a large observation angle as well as a large fill factor, OLEDs themselves consist of light-emitting elements. For this reason and compared with LCDs, no background lighting is necessary. For example, they can be manufactured in the form of a foil, flexible and thin and at low production costs, and can be operated with a relatively low energy input. With their low operating voltage, high energy efficiency as well as the option of manufacturing areal-emitting structural elements for the emission of random colours, the OLEDs are also suitable for application in illuminating elements.

OLEDs are based on the principle of the electro-luminescence where electron-hole-pairs, so-called exzitones recombine under transmission of light. For this purpose, the OLED is constructed in the form of a sandwich structure by which at least one organic film is arranged as active material between two electrodes, whereby positive and negative charge carriers are injected into the organic material, a charge transport of holes and/or electrons to a recombination zone takes place in the organic layer where a recombination of the charge carriers occurs to singulet-exzitones under the emission of light. The following radiating recombination of the exzitones causes the emission of the visible useful light that is discharged from the light-emitting diode. So that this light can leave the structural element, at least one of the electrodes must be transparent. As a rule, this transparent electrode consists of a conductive oxide which is designated as TCO (transparent conductive oxide). The point of commencement for the manufacture of an OLED is a substrate, onto which the individual layers of the OLEDs are deposited. If the electrode nearest to the substrate is transparent, the structural element is designated as a “bottom-emission-OLED”. If the other electrode is executed as a transparent type, the structural element is designated as a “top-emission-OLED”. The same applies in such cases where the electrode between substrate and the at least one organic layer as well as the electrode located away from the substrate are executed as transparent types.

As a substrate, a so-called backplane substrate (rear wall backplane) is used for the displays dealt with here on the basis of organic light-emitting diodes. The circuit-board-conductors, transistors, capacitors and the lower electrode are located on the backplane substrate. In addition, a passivation layer and an isolation layer are deposited onto the substrate. As a standard practice, the organic layers, the upper electrode and finally the encapsulation of the display is applied thereto.

A substantial quality factor of such a display is the so-called fill factor. This fill factor reproduces the ratio of the illuminating sections to the overall surface of the display. The larger the interim spaces between neighbouring pixels, the smaller the fill factor accordingly. As the image impression improves with increasing fill factor, the highest possible fill factor is to be targeted. In the case of top-emitting matrix displays, fill factors of at least 80% are purely theoretically attainable, under due consideration of the rear wall backplane. In actual fact, present OLED matrix displays have a fill factor of 50% as a maximum. This restriction is mainly caused by the masking of the organic layers because, with a full-colour display without filter or conversion layers, it is necessary to process red, green and blue sub-pixels next to each other. The shadow masks used here for this purpose, and the error tolerances related to such, do not allow at present the attainment of fill factors that would be possible based on the manufacturing accuracy of the backplane.

As derived form the definition of the fill factor, this improves if not only light from the electro-optical active areas of the display leaves the structural element, but also from the inactive areas. In this particular case, it must be considered that the varying layers of the OLEDs usually have a different refractive index which is naturally larger than 1. To that extent, not all produced photones can leave the display and be perceived by an observer because total reflections can occur at the various limit surfaces within the structural element and/or between the structural element and the air. Light that is reflected back and forth between two such limit surfaces is ultimately absorbed. The total reflections, as described and depending on the design structure of the OLEDs, can lead to a situation where optical substrate modes, organic modes, meaning modes within at least the one organic layer, and external modes are formed. Only the external optical modes can be perceived by the observer. In this field, various methods are known for the purpose of output coupling of the internal optical modes. This results in an improved degree of efficiency and also in an increased fill factor of the display.

As an example, in the article “30% external quantum efficiency from surface textured, thin-film light-emitting diodes” by I. Schnitzer, Appl. Phys. Lett., Volume 63, page 2174 (1993), it is proposed to roughen the surface of the substrate and, as a result and in a considerable scope, the occurrence of total reflections at the limit surface between substrate and air is avoided. This roughening can be performed, for example, by means of etching or sandblasting the substrate surface which faces away from the organic. In the paper “Improvement of output coupling efficiency of organic light-emitting diodes by backside substrate modification” by C. F. Madigan, Appl. Phys. Lett., Volume 76, page 1650 (2000), the depositing of a spherical pattern on the backside of the substrate surface is described. This pattern can, for example, comprise an array of lenses which is deposited onto the substrate by means of adhesive application or lamination. In the article “Organic light emitting device with an ordered monolayer of silica microspheres as a scattering medium” by T. Yamasaki et al, Appl. Phys. Lett., Volume 76, page 1243 (2000), it is proposed to deposit microspheres consisting of quartz glass onto the surface of the substrate in order to improve the output coupling of the light for an OLED. These microspheres can also be arranged near the OLED in order to scatter light from the internal modes into external modes. Moreover, it is also known to generate periodic structures in the range of the wave length between substrate and first electrode, whereby this periodic structure continues on into the optical active layer of the light-emitting diode. The stated geometry ultimately results in a Bragg-scattering which increases the efficiency of the structural element, refer to J. M. Lupton et al, Appl. Phys. Lett., Volume 77, page 3340 (2000). The German public patent application DE 101 64 016 A1 concerns, moreover, an organic light-emitting diode where at least the one organic layer has various partial areas with different refractive indices. Because of the diversion at the phase limits within the organic, less photones remain captured in the layer due to waveguide losses than with homogenous layers. In addition to this exploitation of intrinsic inhomogeneities in the active organic layer, it is also known to introduce foreign bodies such as nanoparticles into the electronic electro-luminescent material, so that waveguide effects within the organic can be avoided. Refer also, for example, to “Enhanced luminance in polymer composite light emitting devices” by S. A. Carter et al., Appl. Phys. Lett., Volume 71, (1997). These particles suppressing the waveguide effects can consist of TiO₂, SiO₂ or Al₂O₃, can have a size of approx. 30 to 80 nm and can be embedded in a polymer emitter material such as MEH-PPV.

The majority of the approaches stated above with reference to the output coupling of internal modes concern bottom-emitting diodes. The reduction of the waveguide properties of individual layers within the display by the stated approaches, however, does not improve the fill factor of a pixelled structural element. Admittedly, light is radiated also from the inactive areas with the methods as described above. However, the image information of the display gets partially lost because over-radiation and feedover occur between the individual pixels.

### The Invention

The invention therefore aims at further improving the efficiency of the structural element for a display on the basis of an organic light-emitting diode facility.

This task is solved by the invention in a surprisingly uncomplicated manner: on the device side, with a display according to the invention with the features of Claim 1 and, on the method side, with a process for the manufacture of such a display with the features of Claim 13.

In this case the display according to the invention, on the basis of an organic light-emitting diode facility such as an OLED active matrix display, comprises a substrate, a first electrode nearest to the substrate, a second electrode away from the substrate and at least one light-emitting organic layer arranged between both electrodes. The light emitted in the active area transmits through one of the two electrodes whereby the first electrode is pixel-structured and an isolation layer is arranged between neighbouring pixels. The display according to the invention is characterized in that the isolation layer is coupled optically with the light-emitting layer and has optically effective light-scattering heterogeneities whereby the isolation layer is microstructured to match the pixel structure of the first electrode and is processed onto this.

The invention is based on the knowledge of the inventors that a considerable part of the generated light, which does not leave a matrix-structured display, is coupled from the layer configuration consisting of the organic and a transparent electrode into the neighbouring isolation layer where it is reflected several times and finally absorbed. With the avoidance, according to the invention, of the waveguide property of the isolation layer, the light coupled into the isolation layer can leave the structural element at a high percentage rate, through which the desired increase of the fill factor of the structural element results because light is now radiated not only from the electro-optical active areas of the display but also from the inactive areas. In this way the effective pixel area is increased, meaning, the aperture ratio and subsequently the fill factor of the display. By means of skilful setting of the light-scattering properties of the isolation layer, it is avoided that light from a certain pixel is emitted in the first instance in the environment of a neighbouring pixel. In this way, an over-radiation and feedover between individual pixels is avoided.

In addition, the performance efficiency of the structural element is improved so that, ultimately, the display according to the invention can be operated with the same brightness with lower currents as compared with conventional displays. As a result thereof, the life service duration of the display according to the invention is improved. According to the invention and for this particular purpose, the pixel-separating isolation layer is modified by means of suitable processes where the layer is provided with optically effective heterogeneities. This modification of the isolation layer can be achieved with a non-sophisticated processing without causing any damage to the structures already lying underneath. The isolation layer with the display according to the invention has two functions: first, the precise geometrical definition of the pixels lying near one another and secondly the improvement of the performance parameters of each individual pixel by means of an increase of the output-coupling efficiency. This can be achieved, according to the invention, even without the provision of additional process steps during the manufacture of the display according to the invention. The invention is applicable both with top-emitting matrix displays as well as with bottom-emitting matrix displays. The term “matrix display” indicates that the electrode nearest to the substrate, the first electrode is structured particularly for the fixation of display pixels.

In this case, it is appropriate to arrange the layout of the display in such a way that an optical feedover does not occur between neighbouring image points, a situation which would otherwise have a disadvantageous effect on the contrast and/or the colour brilliance. In order to avoid such a feedover between neighbouring pixels, an arrangement can be made to the effect that the density of the heterogeneities, which cause the output-coupling of light from the isolation layer, is selected in such a way that light from a pixel is scattered out within a transversal spacing of x/2 from the display surface, if x is the minimum spacing of two neighbouring pixels. The concentration of the optically effective heterogeneities, which is necessary in order to fulfil this condition, also depends on the size of the heterogeneities.

For the purpose of increasing the fill factor, all optically effective heterogeneities are suitable which can cause a diversion of the light in any random mode, such as by way of scattering, refractive or deflection effects.

In order to avoid colour falsifications with the display according to the invention, it can be envisaged that the optically effective heterogeneities influence the light in a wavelength-independent manner. For this purpose, the heterogeneities should have an expansion that is larger than about one tenth of the operating wavelength. To that extent, the heterogeneities should advantageously have a dimension of somewhat more than 50 nm in order to avoid the stronger scattering of blue light than red light by way of the Rayleigh-scattering.

In order to avoid that the light coupled from the organic into the isolation layer excessively absorbs in the isolation layer, it can be envisaged that the absorption coefficient of the isolation layer is smaller than 10⁵ m⁻¹, advantageously smaller than 10⁴ m⁻¹ in particular. In this way it can be ascertained that the penetration depth of the light emitted in the active layer into the isolation layer is at least 10 μm, advantageously more, however. It is appropriate to coordinate the layers of the display according to the invention on each other in such a way that as much light as possible is coupled from the internal optical modes, captured in the organic and the transparent electrode, into the isolation layer. This can be achieved in such a way that the refractive index of the isolation layer is set equal to or greater than that of the layer structure, consisting of the organic and the transparent electrode. In this case there is no total reflection for light from the layer structure, which progresses in the direction of the isolation layer, at the limit surface layer structure/isolation layer. The follow-up output-coupling from the isolation layer can, however, be reduced with such a large refractive index because of the total reflection occulting then. To that extent, the refractive index of the isolation layer should be preferably in the same ranges as the refractive index of the organic and the transparent electronics. This range lies appropriately between 1.3 and 2.2, particularly advantageous between 1.6 and 2.0 and depends mainly on the special layer material of the organic and the electrode, respectively.

It is appropriate if the thickness of the isolation layer is between 0.1 μm and 20 μm, particularly advantageous between 0.2 μm and 5 μm. In this case it is appropriate if the isolation layer is not selected too thin as it would otherwise not conduct light modes and could not render any support for their output-coupling. On the other hand, the maximum thickness is limited by the spacing between two neighbouring pixels. The inventors have discovered that it is appropriate when the thickness is not larger than x/2, if the minimum spacing between two neighbouring pixels is x.

A particularly effective embodiment of the display according to the invention results if the optically effective heterogeneities are arranged within the isolation layer, whereby the heterogeneities have a size from approx. 0.05 μm to 5 μm. Particles of this size have Mie-scattering properties and are subsequently not or scarcely wavelength-selective. The volume concentration of the particles can preferably be between 0.3*d/x and 10*d/x, whereby d is the typical mean diameter of the scatter particles and x is the minimum spacing between neighbouring pixels. In this way, the feedover of neighbouring pixels is avoided.

Methods for the wet-chemical depositing of the material of the isolating layer can be, for example, various printing methods (such as inkjet printing, screen printing, flexo-printing, tampon printing and further high-pressure, low-pressure, flat-pressure and through-pressure methods). In addition, other methods are also possible such as blading, spin-coating, dip-coating, roll-coating, spraying and others. As materials for the isolation layer, pure photo-resists (preferably positive resists) or for example also photo-sensitive emulsions can be advantageously used. Such watery or organic emulsions typically consist of a layer former, sensitizers or photo-initiators and diverse additive substances. For example, melamine resins, polyvinyl alcohol, polyacrylate or also polyvinyl acetate can be used as layer formers. As these are not sensitive to light, such emulsions are given, for example, diazo compounds or stilbazole-quartered compounds (SBQ) which cross-link the layer formers when light incidence occurs and provide for a form-stable layer in this way.

It can be appropriate if the isolation layer, without further additives, has scattering properties solely by means of intrinsic heterogeneities such as spatially separated varying phases or phase limits in the stated magnitude. Moreover, it can also be advantageous to incorporate extrinsic heterogeneities into the isolation layer, for example in the form of scattering particles which are dispersed directly in a matrix material. With regard to their optical properties, these scattering particles differ from those of the other layer material.

Such extrinsic heterogeneities can be selected from a large number of particles, in particular:
Inorganic micro-crystals such as salt crystals or metal oxides, such as silicates, sapphire-micro-crystals, MgO, SiO₂;
Organic micro-crystals such as carbohydrates or crystallised polymer particles such as starch, cellulose or synthetic polymers such as polyamide, PEDOT: PSS-crystals;
Aerosils;
Inorganic amorphous materials such as quartz glass (SiO2);
Nanoparticles;
Powder of polymers (polycarbonates, polyacrylates, polyimides, polyesther, PE, PP, polyether, fluoropolymers, polyamides, polyvinylacetates);
Powder of non-polymer organic materials (aromates, aliphates, heterocycles);
Gas bubbles which are incorporated mechanically into the matrix solution, for example by means of foaming with inert hydrocarbons (pentane), inert gases (Ar), N₂, CO₂ or CFC;
Gas bubbles incorporated into the matrix solution in a chemical manner by means of, for example, the sequence of a chemical reaction where a gaseous reaction product such as CO₂, N₂ originates (for example: SBQ with light incidence reacts with the occurrence of nitrogen).

With the use of conductive scattering particles for the formation of the optically effective heterogeneities in the isolation layer, the concentration is to be set appropriately in the layer with due consideration of the size of the particles so that no electric short-circuits occur.

Particularly with the execution of the display according to the invention as a top-emitting structural element, it can be appropriate if a hole transport layer is arranged between the electrodes, where said layer is p-doped with an acceptor-type organic material and has a thickness of between 20 in and 2 μm, particularly a thickness of between 30 nm and 300 nm. Such a doping results in an increased conductivity, so that such transport layers can have higher layer thicknesses than usual in comparison with non-doped layers (typically 20 to 40 nm), without causing a drastic increase of the operating voltage. The presence of a thick charge transport layer between the light-emitting organic layer and the transparent second electrode provides in particular a protection for the light-emitting layer with the manufacture of the second electrode and further subsequent process steps, respectively. The stated transport layer, depending on the embodiment, can also be established as electron transport layer which is n-doped with a donor-type organic material and has a thickness of between 20 nm and 2 μm, particularly a thickness of between 30 nm and 300 nm.

In addition to the wet-chemical deposition of the isolation layer, this can also be sputtered on, grown-on or separated. Suitable processes for this purpose are: sputtering, PVD (physical vapor deposition), CVD (chemical vapor deposition), PECVD (plasma enhanced chemical vapor deposition), MBE (molecular beam epitaxy), MEE (molecular enhanced epitaxy), MOVPE (metal organic vapor pressure epitaxy) and OVPD (organic vapor phase deposition). The structuring of the isolation layer is performed, after its production, again appropriately with the help of wet-chemical or dry-chemical structuring methods.

Appropriate layer materials are;
Transparent metal oxides (e.g., SiO₂, ZnO, ZrO₂, Al₂O₃, TiO₂, Ga₂O₃)
Transparent metal nitrides such as Si₃N₄
Organic materials such as aromates, aliphates, heterocycles and ketones

Depending on the material adopted for the isolation layer, different methods for putting the scattering centres into the layer can be used advantageously. An amorphous film can result with the sputtering of metal oxides such as SiO₂ or metal nitrides. For this reason, and for the establishment of the isolation layer, the material of the isolation layer and the material forming the scattering centres can be sputtered on or vapor-deposited in an alternating manner. Furthermore, the alternating sputtering of the material of the isolation layer and the deposition of micro-metal particles with the help of cold-spray methods is an appropriate process. With such a cold-spray method, for example, a metal powder such as copper powder can be used in order to put scattering centres of the magnitude stated above into the isolation layer. In addition to this, it can be appropriate to alternatingly sputter the isolation layer material and a metal, in order to put the required scattering centres into the isolation material. Care must be exercised in this case that the metal is only briefly sputtered on in order to avoid the formation of a continuous metal film instead of individual metal clusters, so that an isolation through the layer is no longer ensured. An advantageous thickness of such metal clusters is smaller than 20 nm.

In cases where the isolation layer is vapor-deposited from the gas phase, it can be appropriate to select the vapor-deposition parameters in such a way that the formation of polycrystalline microstructures and dislocations are given preference. In this way it is possible to generate intrinsically the required optically effective heterogeneities in the isolation layer so that no extrinsic scattering particles have to be brought into the layer.

With the use of organic layer material for the isolation layer, a self-crystallising or a self-partial-crystallising organic layer can also be advantageously vapor-deposited where again the incorporation of extrinsic heterogeneities into the layer is not necessary. For the purpose of putting scattering centres into vapor-deposited organic layers, it can be appropriate when, for example, micro-metal particles or metal oxide clusters as scattering centres are put into the isolation layer by means of sputtering or a cold-spray method. In addition to this, it is also advantageously possible to vapor-deposit clusters of semiconductor connections between the organic layers which form in common the isolation layer. Accordingly, the isolation layer in the display according to the invention can consist of several layers.

In a further advantageous embodiments it can be envisaged to produce optically effective heterogeneities on the surface of the isolation layer in order to obtain an output-coupling of light from this layer. For this purpose, the surface of the isolation layer is roughened whereby these roughenings have a dimension of between 0.05 and 20 μm. In this case, all materials can be used in principle for the formation of the isolation layer as stated above for embodiments where the optically effective heterogeneities are produced in the layer. The roughening of the isolation layer at the surface can be performed advantageously, for example, with the following methods:
Micro-structuring of the layer by means of photo-lithographic techniques;
Reactive dry etching;
Non-reactive dry etching;
Wet-chemical etching (e.g., with acids);
Stamping with a micro-structured stamp.

With all these methods, the process parameters are to be appropriately selected in such a way that the rear wall backplane and/or its elements are not damaged. To that extent it is appropriate if the isolation layer and the lower electrode have a large mechanical and/or chemical stability which can be achieved, depending on the embodiment, by providing bi- or multi-layer for the individual layer.

As stated, it can be appropriate to carry out the structuring of the surface of the isolation layer by means of stamping with a stamp form, through which the material of the isolation layer is either permanently deformed or split section-wise. The desired structured surface is obtained in both cases and this improves the light output-coupling from the isolation layer. In order to protect the rear wall backplane and/or its structural elements, it can be appropriately envisaged to form the stamp in such a way that the forces applied to the isolation layer with this embossing action run essentially longitudinally to the layer. In principle, the stamping of wet-chemically processed isolation layers can take place during or after the hardening of the layer. Particularly advantageous with reference to the mechanical loading of the rear wall backplane and/or its structural elements is the application of the roughening by stamping of the isolation layer before its hardening. Also particularly advantageous in this respect is the structuring of the surface by means of a technique based on the screen printing method. In this case, all materials can be used as isolation layer material which can be wet-chemically or dry-chemically structured. Such a layer is deposited onto the rear wall backplane and/or the structured electrode and is structured by placing and pressing a fabric thereon. For this purpose, for example, the blading known from the screen printing method is suitable, for example under the usage of polyurethane blades. As stated, it is necessary in this case that the deformation caused by the stamping remains intact also after the hardening of the isolation layer.

Particularly advantageous embodiments of the invention can be manufactured where optically effective heterogeneities are produced both in the isolation layer as well as on the surface, so that particularly effective light of the internal modes is output-coupled from the isolation layer. Such displays according to the invention have a particularly good output-coupling of light from the isolation layer for the purpose of improvement of the fill degree and/or for the improvement of the energy efficiency.

On the process side, the task according to the invention is solved by a method for the manufacture of a display on the basis of an organic light-emitting diode facility, particularly of an OLED active matrix display with the steps: provision of a substrate onto which a display electronic is applied, deposition of a passivation layer onto the display electronic with lead-throughs to the display electronic, application of a pixel-structured first electrode onto the passivation layer, application of a structured isolation layer onto the structured first electrode, application of at least one light-emitting organic layer and application of a second electrode. As stated above, the isolation layer is provided with optically effective, light-scattering heterogeneities.

Moreover, the person skilled in the art recognise that it can be advantageous and that it lies within the framework of the invention when the isolation layer is established according to one of the methods, as described here, of the state of the art for the output-coupling of internal modes

### PREFERRED EMBODIMENTS OF THE INVENTION

The invention is explained as follows in greater detail with the description of some embodiments with reference to the attached drawings. The drawings show the following:

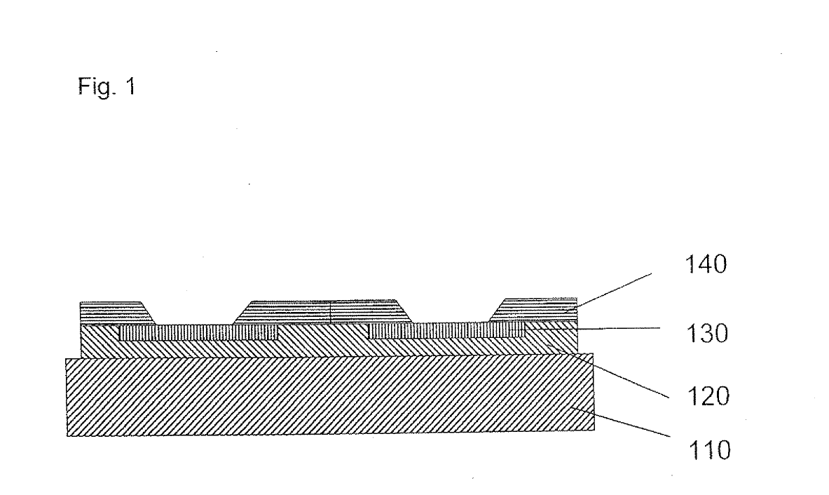

FIG. 1 a substrate with a passivation layer and an isolation layer for a display according to the invention in a principle illustration;

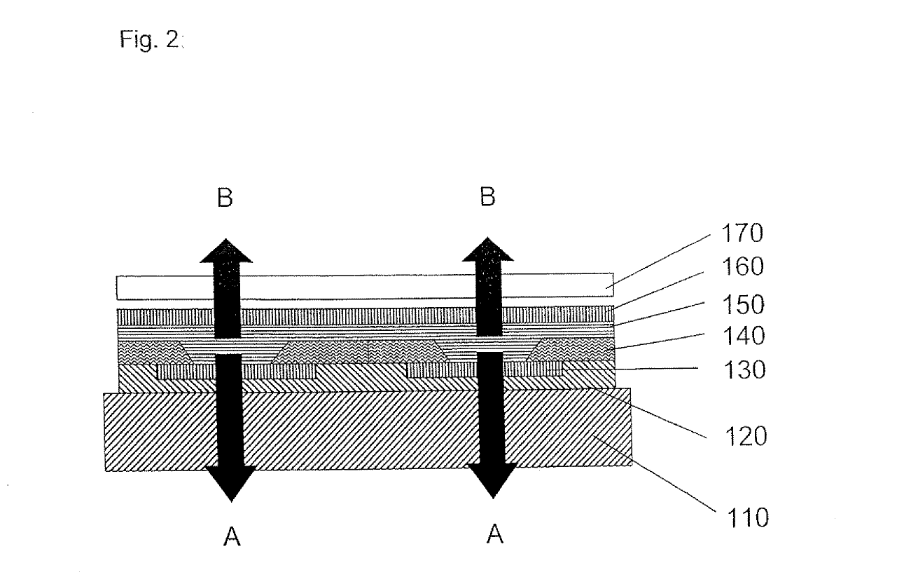

FIG. 2 the substrate shown in FIG. 1 after processing of the organic layers, the upper electrode and the encapsulation;

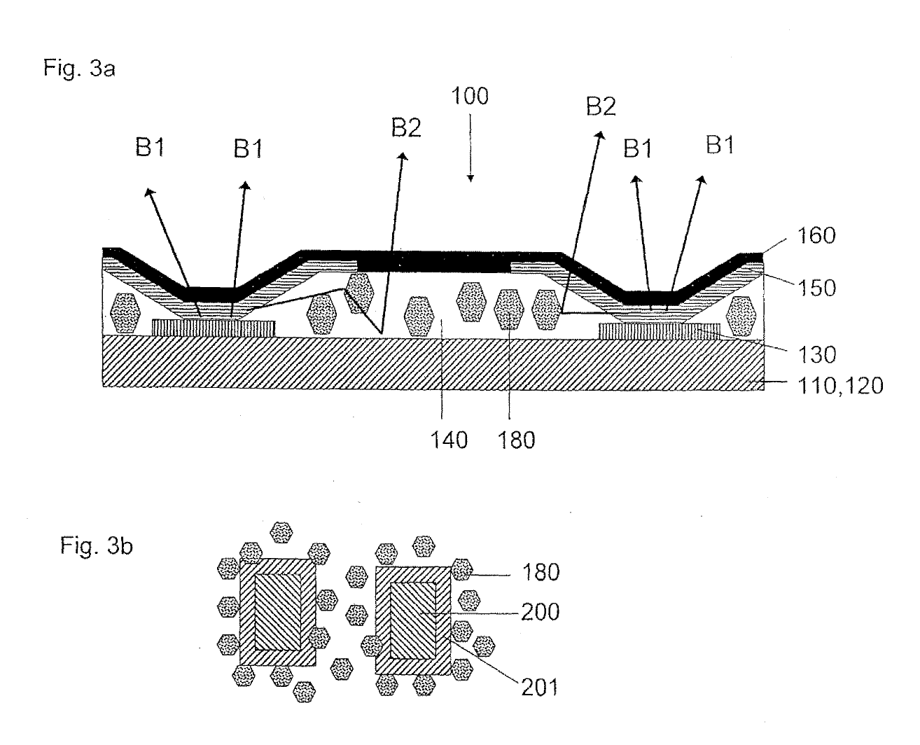

FIG. 3a a first embodiment of an arranged display according to the invention with top emission;

FIG. 3b for the display shown in FIG. 3a, the arrangement of optically effective heterogeneities in the isolation layer with reference to the pixel structuring;

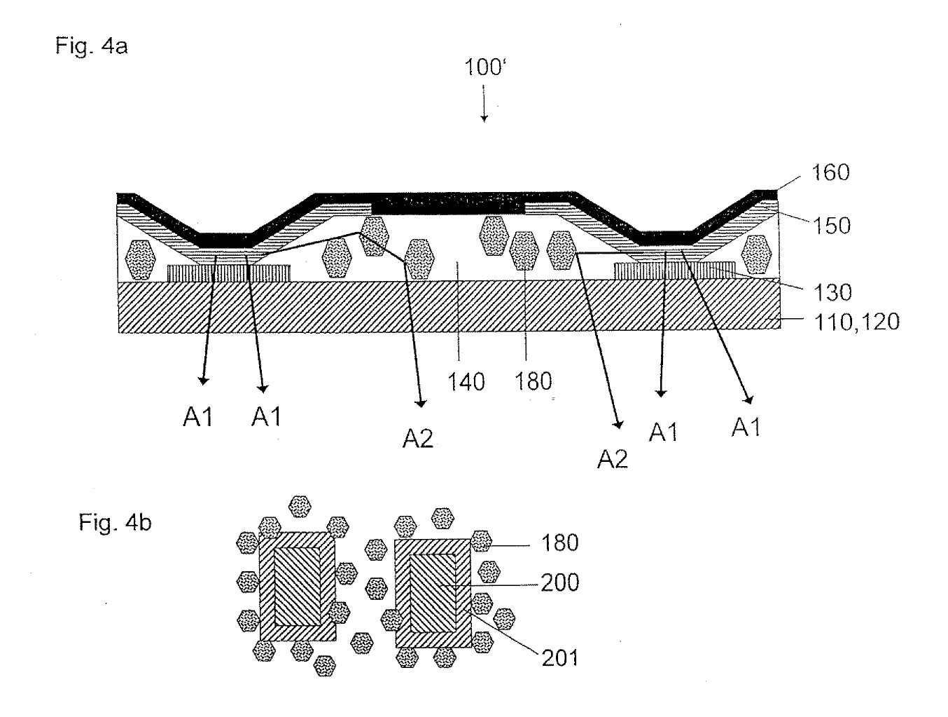

FIG. 4a a second embodiment of an arranged display according to the invention with bottom emission;

FIG. 4b for the display shown in FIG. 4a, the arrangement of optically effective heterogeneities in the isolation layer with reference to the pixel structuring;

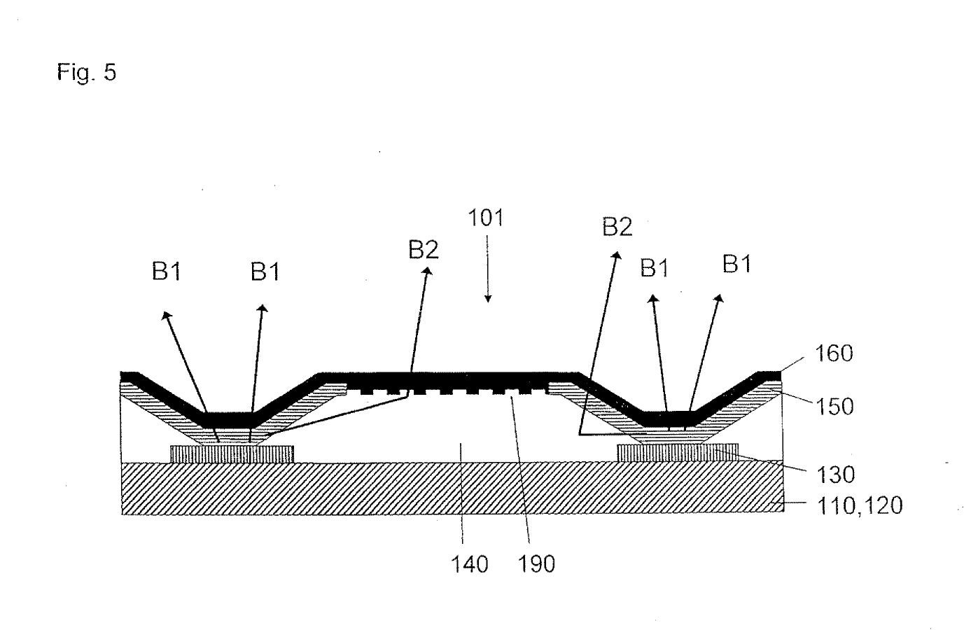

FIG. 5 a third embodiment of a display according to the invention with top emission in a principle sketch with surface structured isolation layer;

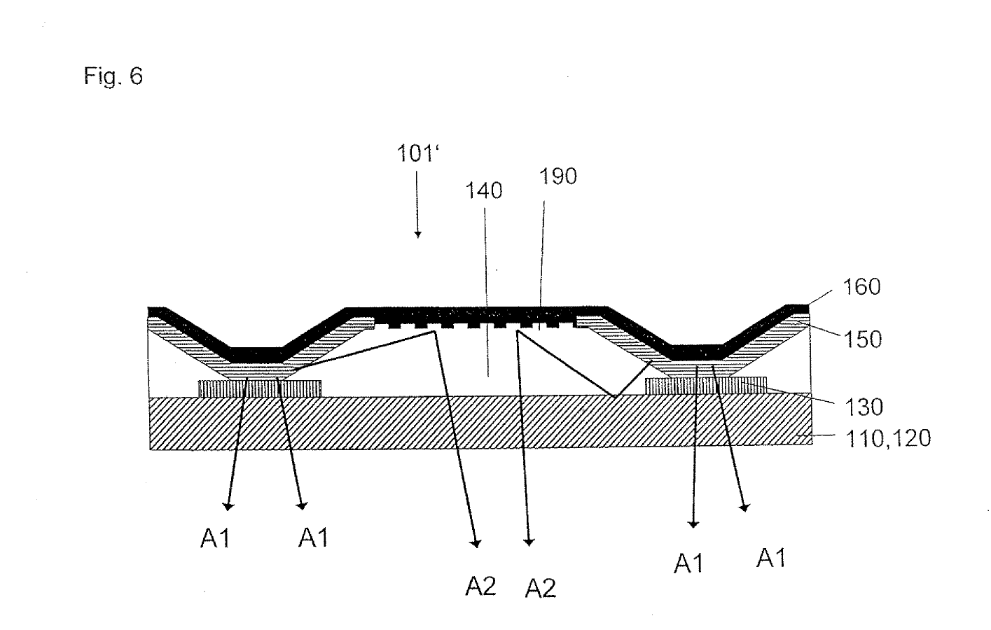

FIG. 6 a fourth embodiment of a display according to the invention with bottom emission in a principle sketch with surface structured isolation layer;

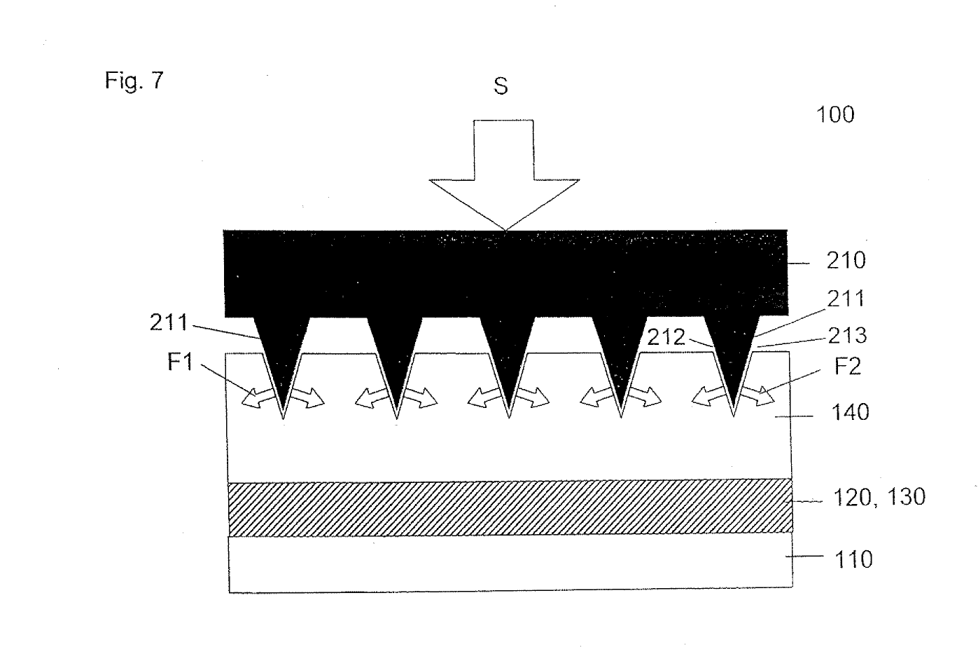

FIG. 7 in a principle sketch the structuring of the surface of the isolation layer with a stamp; and

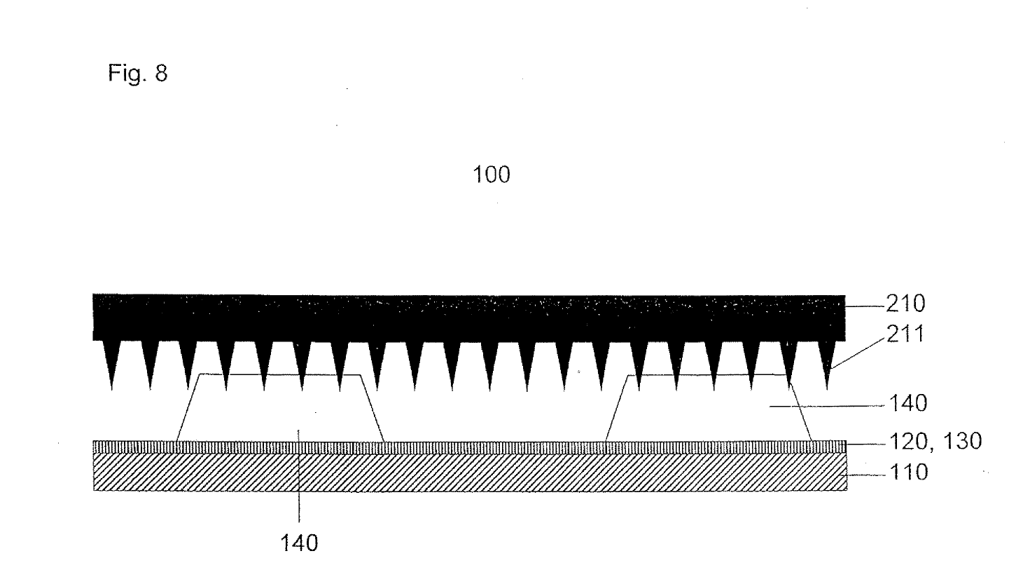

FIG. 8 the structuring of the isolation layer of an active matrix display with a stamp.

The invention is explained as follows with reference to the configuration of active matrix displays. Point of commencement of the manufacture is a so-called backplane substrate 110 where the circuit-board conductors, semiconductors and capacitors are applied to a glass substrate, refer to FIG. 1. In the Figure, the passivation layer is stated with the reference number 120. Then, the pixel-structured first electrode 130 is applied to the passivation layer. As shown, individual sections of the electrode 130 are separated from one another and, in this way, form individual pixels of the display. For the precise definition of the individual pixels, and in the following step, an isolation layer 140 from a non-conducting material is applied. This must be structured micrometer-exactly corresponding to the pixel structure of the electrode. Furthermore, caution must be exercised here that, with the processing and structuring of the isolation layer, the layers lying beneath, meaning the substrate with the electronic 110 and the passivation layer 120 as well as the first electrode 130 processed thereon, are not damaged. As the principle structural configuration of the active matrix display according to the invention is to be explained in advance, the processing and the structural arrangement of the isolation layer 140, as shown in FIG. 1, will be dealt with below later.

The complete principle structural configuration of the active matrix display is shown in FIG. 2. Onto the first electrode and the isolation layer 140, one or several organic layers are applied. In the Figure, the layer structure has the reference number 150. Onto this, the upper second electrode 160 is processed. As a rule, and as stated in the Figure, an encapsulation 170 closes off the display for the purpose of protection against outer influences. Depending on the specific embodiment, the display can discharge light through the substrate 110 or by way of the upper electrode and the encapsulation. In the first case, (arrows A) the structural element is designated as bottom emission display. In the second case, (arrows B) as top emission display. By way of the specific configuration of the substrate and the two electrodes, it is stipulated whether light is discharged downwards through the substrate or upwards. The simplest method can be to make one of the two electrodes as light-reflecting and non-transparent. As a rule, the display is constructed in such a way that the electro luminescence light generated in the organic layer structure is either radiated downwards through the substrate or upwards in the opposite direction, meaning, it leaves the structural element. In specific embodiments it is possible without problems, on the other hand, that the light is radiated both downwards as well as upwards. For this purpose, all deposited layers have the necessary transparency so that the photones can transmit through each of the layers.

FIG. 3a shows in a principle sketch a first embodiment whereby the active matrix display is constructed in a top-emitting manner. The backplane comprises a glass substrate with display electronic 110, onto which the passivation layer 120 is deposited in a conventional manner. This is followed by a reflecting electrode 130 which is structured in a photo-lithographic manner for the fixation of the pixel structure of the display. In the illustrated example a photo-resist, to which 5 vol.-% sapphire crystals with a particle size of approx. 0.5 μm are added, is deposited by spin-coating with a thickness of 2 μm. The photo-resist has an absorption coefficient of approx. 10³ m⁻¹ in a wavelength range of 350-780 nm. The isolation layer is also photo-lithographically structured according to the pixel structure of the first electrode. The organic layer structure 150 can now be deposited in a conventional manner. In the example as presented, the organic layers are applied to the electrode 130 and the isolation layer 140, respectively, by means of thermal vapor-deposition of the corresponding materials. Finally, a transparent cover electrode 160 from a conductive oxide is thermally vapor-deposited. Not shown is an encapsulation layer which is normally applied to the cover electrode 160 for the protection of the display. As can be seen, the optically effective scattering particles 180 in the form of sapphire crystals are distributed homogenously in the isolation layer 140.

As implied in FIG. 3a, electro luminescence is generated within the organic layer structure 150 between the electrodes 130, 160. A part of the generated light transmits through the upper electrode 160 and leaves the configured display. This light which is generated within the individual pixel surface and which leaves also the structural element within this surface is designated in the FIG. 3a as B1. By contrast, a part of the electro luminescence light leaves the organic layer structure 150 with a propagation component longitudinally to the layer structure. As stated in the Figure, this light can be scattered at the scattering particles (sapphire crystals) 180, through which the direction of propagation is changed in such a way that the light is scattered either directly upwards in the direction towards the second electrode 160 or only after a reflection at the backplane which comprises the glass substrate with display electronic 110 and the passivation layer 120. Understandably, of course, multiple scatterings can also occur at several such optically effective heterogeneities. Ultimately, and as a result of the described configuration of the isolation layer 140) the volume of the photones increases which can leave the structural element through the cover electrode 160. The output-coupled light emerging, by means of the special configuration of the isolation layer, is marked with the arrows B2 in FIG. 3a. So that no feedover occurs at two neighbouring pixels of the display structure, the density of the sapphire crystals in the layer is set in such a way that light, which is emitted in the longitudinal direction from the organic layer structure 150, is scattered out within a section in the longitudinal direction from the structural element in the upward direction, that is smaller than half of the pixel spacing, amounting here to 20 μm.

FIG. 3b shows in a view schematically the structured first electrode in a partial section of two pixels with the isolation layer 140 lying in between, which comprises the stated scattering particles 180. With the reference number 200, the geometric surface of a pixel, meaning the geometric surface of the electrode section illustrating a single pixel, is shown. Based on the scattering effect of the particles, the effective pixel surface 201 appears to be enlarged for an observer.

After the encapsulation and for the completion of the active matrix display according to the invention, the structural element must now be provided with the corresponding control activation. Based on the described configuration of the isolation layer 140, the performance efficiency, the life service duration and the image impression improve compared with displays that are manufactured in a conventional manner without modification of the isolation layer 140.

A second active matrix display is shown in FIG. 4a. The only difference to the display as shown in FIG. 3a is that the first electrode 130 is transparent in design while the cover electrode 160 is reflective in design. Subsequently, the directly output-coupled light (arrows A1) and the light (arrows A2) additionally output-coupled by the scattering particles 180 leave the bottom-emitting display through the substrate 110. In particular, the isolation layer 140 is, however, identical with the top-emitting display that is shown in FIG. 3a.

FIG. 4b shows again the enlargement of the effective pixel surface 201 compared to the real pixel surface 200. The person skilled in the art recognises that these conditions, compared with the examples shown in the FIGS. 3a and 3b, are unchanged.

FIG. 5 shows a further embodiment of a configured active matrix display that is designed as a top-emitting structural element. Again, the same structural elements of the display are stated with the same reference number as in the previous embodiments, in which case here the encapsulation is not shown. The only difference in the arrangement of the embodiment shown in FIG. 5 to that shown in FIG. 3a is that the isolation layer 140 consists of a pure photo-resist without added particles. This is deposited onto the electrode 130 and the passivation layer 120, respectively, in a conventional way and manner. The surface of the isolation layer 140, which lies on the second electrode or cover electrode 160, is treated mechanically for the generation of the optically effective heterogeneities. For this purpose, the wet-chemically deposited photo-emulsion is structured by the placing and pressing of a fabric on its surface. The system of blading known from the screen printing method is applied for pressing on the fabric. The roughening of the surface is followed by the usual structuring of the isolation layer which is adapted to the pixel structuring of the first electrode 130. As a final operation, the hardening of the isolation layer and the deposition of the organic layer structure 150 and the cover electrode 160 according to the known methods. Also with the embodiment as shown in FIG. 5, and in addition to the directly output-coupled light B1 based on the scattering of spreading light along the layer longitudinally at the roughening 190 of the isolation layer 140, scattering is effected and light emerges via the transparent electrode 160 from the display (arrow B2).

FIG. 6 shows a further embodiment of an active matrix display which, with reference to the isolation layer 140, is structured identically to that display shown in FIG. 5. However, the display 101′ does not function as a top-emitting display but rather as a bottom-emitting structural element.

FIG. 7 shows in a principle sketch the structuring of the isolation layer 140 in the form of a pure photo-resist emulsion that is wet-chemically applied onto the passivation layer 120 and the lower electrode 130 which is itself is connected to the substrate 110. For the surface structuring of the isolation layer, a stamp 210 is used which has a large number of equally spaced edges 211 which are formed by two tapered edge surfaces 212, 213. For the structuring, the stamp 210 is placed onto the surface of the isolation layer 140 and pressed into this with a pre-specified stamping force S. With the stated arrangement of the edges 211, a force pattern is established in the isolation layer 140 as shown by the arrows F1, F2. As can be seen from the Figure, a large part of the applied stamp force is discharged laterally within the isolation layer 140 as a result of the stated arrangement of the stamp so that the layers lying beneath, such as the passivation layer 120 and the substrate including the electronic 100, are not strained in the process. In the stated example, the stamp is made of hardened high-quality steel whereby the individual edges 211 of the stamp have a lateral expansion of 0.5 μm. Its spacing is approx. 2 μm. After removal of the stamp, the surface of the isolation layer 140 is structured with a large number of equally spaced grooves because the splitting of the layer on its surface is irreversible. Accordingly, these grooves and/or their limiting surfaces form the optically active heterogeneities at which the light conducted within the isolation layer is led to the outside. As in the case of all usable optically active heterogeneities, and depending on the special arrangement involved, this light guiding can contain a light scattering, light refringency and/or light diffraction. To this extent, the term “scattering” is not limited to a pure scattering of light.

FIG. 8 shows the generation of optically effective heterogeneities at the surface of the isolation layer 140 of an active matrix display in a larger section. In this case also, the stamp 210 is pressed into the isolation layer 140 in the way and manner as described with reference to FIG. 7. One recognises that the stamp does not damage the lower electrode 130 and the passivation layer 120.

Attention is drawn here to the fact that, in the embodiments as described, only a small portion of the possible active matrix displays according to the invention on the basis of organic light-emitting diodes are stated herein. In principle, all methods and materials stated in the description introduction for the production of a specific active matrix display according to the invention are usable.

1. Structural element on the basis of an organic light-emitting diode facility, particularly an OLED active matrix display, comprising a substrate, a first electrode nearest to the substrate, a second electrode away from the substrate and at least one light-emitting organic layer arranged between both electrodes whereby emitted light transmits through at least one of the two electrodes, and the first electrode is structured in pixels whereby an isolation layer is arranged section-wise between neighboring pixels, characterized in that the isolation layer is coupled optically with the light-emitting layer and has optically effective light-scattering and fill factor increasing heterogeneities where the isolation layer is micro-structured to match the pixel structure of the first electrode and is processed thereon.

2. Structural element according to claim 1, characterized in that the isolation layer has a refractive index 1.3 and 2.2, particularly between 1.6 and 2.0.

3. Structural element according to claim 1, characterized in that the thickness d of the isolation layer is between 0.1 μm and 10 μm, particularly between 0.2 μm and 5 μm, whereby d is smaller that the half of the minimum spacing x of two neighboring pixels.

4. Structural element according to claim 1, characterized in that the heterogeneities are arranged within the isolation layer, whereby the heterogeneities have a size of approximately 0.05 μm to 5 μm.

5. Structural element according to claim 4, characterized in that the volume concentration of the heterogeneities lies between 0.3*b/x and 10*b/x, whereby b is the mean diameter of the heterogeneities and x is the smallest spacing of two neighboring pixels.

6. Structural element according to claim 1, characterized in that the isolation layer has a matrix material.

7. Structural element according to claim 6, characterized in that the matrix material has extrinsic, optically active heterogeneities.

8. Structural element according to claim 1, characterized in that the isolation layer comprises intrinsic, optically active heterogeneities, particularly spatially separated different phases or phase limits of the material of the layer.

9. Structural element according to claim 1, characterized in that the heterogeneities are arranged on the surface of the isolation layer, and have a dimension of approximately between 0.05 μm and 10 μm.

10. Structural element according to claim 1, characterized in that between the electrodes, a hole transport layer is arranged which is p-doped with an acceptor-type organic material and has a thickness between 20 nm and 2 μm, particularly a thickness between 30 nm and 300 nm.

11. Structural element according to claim 1, characterized in that, between the electrodes an electron transport layer is arranged which is n-doped with a donor-type organic material and has a thickness between 20 and 2 μm, particularly a thickness between 30 nm and 300 nm.

12. Structural element according to claim 1, characterized in that, between the electrodes an electron transport layer is arranged which is n-doped with an alkaline material and has a thickness between 20 and 2 μm, particularly a thickness between 30 nm and 300 nm.

13. Method for the manufacture of a structural element on the basis of an organic light-emitting diode facility, in particular an OLED active matrix display, with the steps:
Provision of a substrate,
Application of the display electronic onto the substrate
Deposition of a passivation layer with lead-through to the display electronic onto the display electronic,
Application of a pixel-structured first electrode, which is electrically conductive through the lead-throughs of the passivation layer connected to the display electronic, onto the passivation layer,
Deposition and structuring of an isolation layer onto the structured first electrode,
Deposition of at least one light-emitting organic layer,
Application of a second electrode,
characterized in that, the isolation layer is provided with optically effective light-scattering and fill factor increasing heterogeneities.

14. Method according to claim 13, characterized in that the isolation layer is sputtered, grown or separated onto the first electrode.

15. Method according to claim 13, characterized in that the isolation layer is wet-chemically deposited onto the first electrode.

16. Method according to claim 15, characterized in that the isolation layer is formed from a matrix material, into which scattering particles with pre-specified dimensions are mixed.

17. Method according to claim 14, characterized in that the isolation layer is vapor-deposited from the gas phase whereby the vapor-deposition parameters are selected in such a way that the formation of polycrystalline microstructures and offsets is preferred.

18. Method according to claim 14, characterized in that the material forming the optically effective heterogeneities is put in by means of a cold spray method.

19. Method according to claim 14, characterized in that, for the purpose of the formation of the isolation layer, at least one self-crystallising or one self-partial crystallising organic layer is vapor-deposited.

20. Method according to claim 14, characterized in that, for the purpose for formation of the isolation layer, the material of the isolation layer and the material forming the scattering centres is alternatingly sputtered on or vapor-deposited.

21. Method according to claim 13, characterized in that the optical heterogeneities are produced on the surface of the isolation layer which faces away from the second electrode.

22. Method according to claim 21, characterized in that, by means of the pressing of a micro-structured stamp or a fabric into the outer surface of the isolation layer, this surface is structured.

23. Method according to claim 22, characterized in that the stamp is executed in such a way that the forces, applied to the isolation layer during the embossing action, essentially run longitudinally to the layer.

24. Method according to claim 21, characterized in that the outer surface of the isolation layer is structured by means of a photo-1
